(19) United States
(12) Patent Application Publication
(10) Pub. No.: US 2004/0256628 A1
(43) Pub. Date: Dec. 23, 2004

(54) Optical source having integral diffractive element

(76) Inventors: Yee Loong Chin, Lahat (MY); Kee Siang Goh, Peneng (MY); Boon Kheng Lee, Alor Setar (MY); Siang Leong Foo, Ayer Itam (MY); Cheng Why Tan, Mertajam (MY)

Correspondence Address: AGILENT TECHNOLOGIES, INC., Legal Department, DL429, Intellectual Property Administration, P.O. Box 7599, Loveland, CO, 80537-0599, US

(21) Appl. No.: 10/602,374

(22) Filed: Jun. 23, 2003

(51) Int. Cl. H01L 21/00; H01L 33/00

(52) U.S. Cl. 257/98; 257/100; 257/99; 438/22

(57) ABSTRACT

An optical source includes an optical emitter with an encapsulant covering the optical emitter. A diffractive element is integrated into the encapsulant, wherein the encapsulant passes an optical signal from the optical emitter to the diffractive element.

### BACKGROUND OF THE INVENTION

Known light sources that use LEDs (light emitting diodes) pattern emitted light using refractive or reflective structures. Common refractive structures, as shown in the light source of FIG. 1A, include dome-profile encapsulants 1 that encase the LED. The emitted light pattern is influenced by the shape of the refractive structure and is typically controlled by making the refractive structure spherical, aspherical or oval. Another common light source (shown in FIG. 1B) includes a flat-top encapsulant 2, forming an air-gap device. While the shape of the flat-top encapsulant 2 enables the light source to be compatible with higher level packaging and assemblies, the shape provides only limited refraction and correspondingly little patterning of the light emitted by the LED.

Light sources also include reflective optical structures to pattern light emitted by an LED. For example, LEDs are commonly positioned in a parabolic reflector cup 3 as shown in FIG. 2. Alternatively, optical elements based on total internal reflection (not shown) as taught by U.S. Pat. No. 5,592,578 to Richard A. Ruh can be positioned in the optical path of an LED to pattern the emitted light.

### SUMMARY OF THE INVENTION

An optical source according to embodiments of the present invention has an optical emitter and a diffractive element integral with an encapsulant. Alternative embodiments of the present invention are directed toward a method for generating an optical radiation pattern.

### BRIEF DESCRIPTION OF THE DRAWINGS

FIGS. 1A-1B show prior art LEDs that include refractive structures.

FIG. 2 shows a prior art LED that includes a reflective optical structure.

FIG. 3 shows an exemplary diffraction grating.

FIGS. 4A-4D show optical sources according to embodiments of the present invention.

FIGS. 5A-5E show detailed views of exemplary grating profiles of diffractive elements suitable for inclusion in the optical sources according to the embodiments of the present invention.

FIG. 6 shows a method for generating an optical radiation pattern in accordance with alternative embodiments of the present invention.

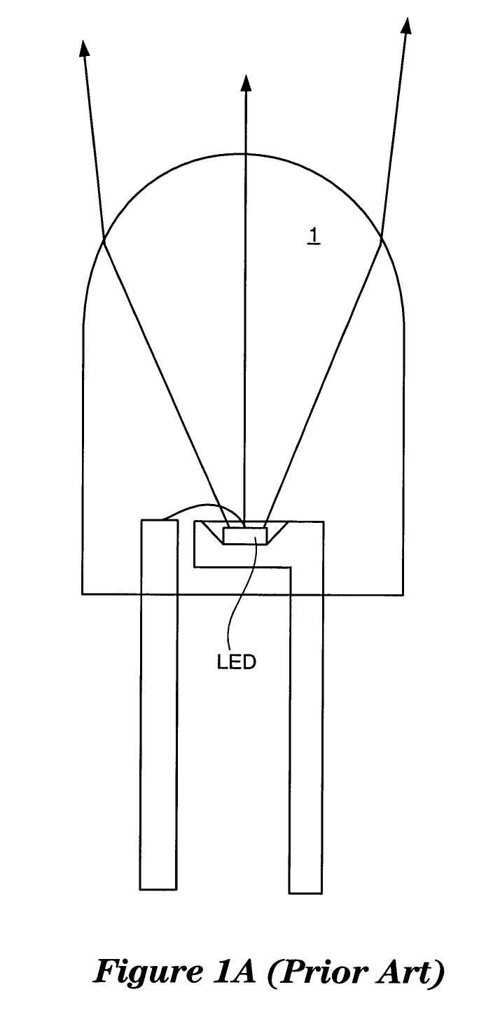

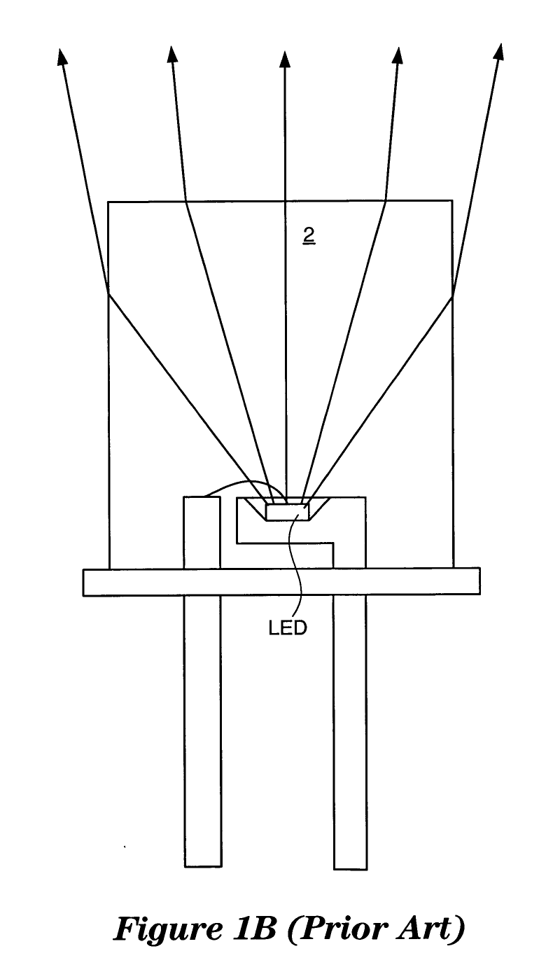

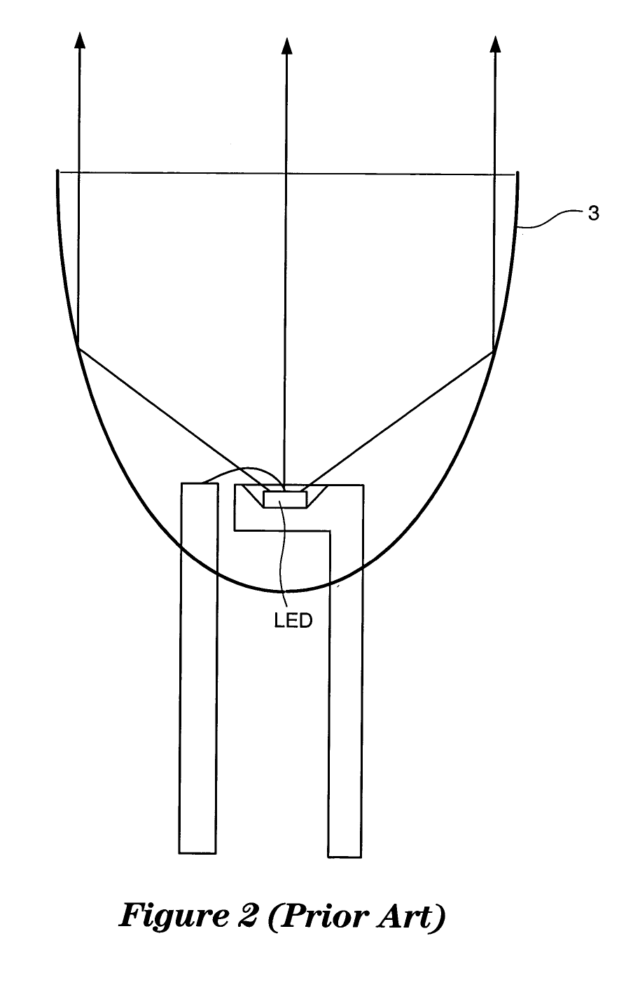

### DETAILED DESCRIPTION

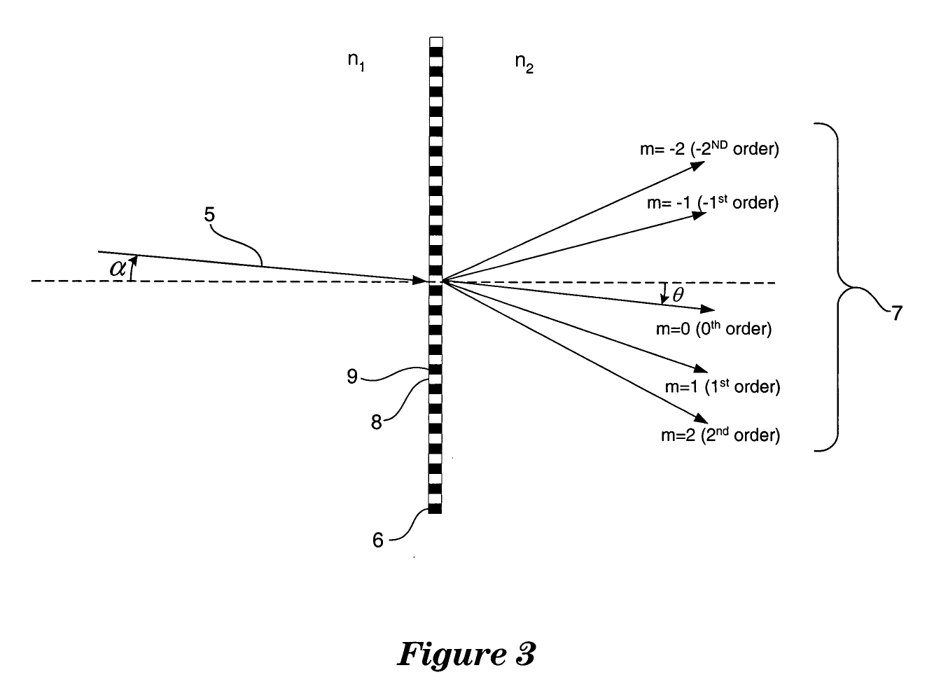

Diffraction of light by diffraction gratings, slits and other obstacles having physical dimensions on the order of the wavelength of the incident light is well known. FIG. 3 shows an incident optical signal 5 illuminating a diffraction grating 6. The diffraction grating 6 in this example has uniformly-spaced alternating transmissive segments 8 and opaque segments 9. The transmissive segments 8 in this diffraction grating 6 form an array of slits or apertures. Diffraction of the incident optical signal 5 by the diffraction grating 6 is characterized by the grating equation:

d(n₂ sin α−n₁ sin θ)=mλ

where d is the distance between adjacent transmissive segments 8, or slits, of the diffraction grating 6; n₁ is the refractive index of the medium containing the incident optical signal; n₂ is the refractive index of the medium containing diffracted beams 7; α is the incident angle of the incident optical signal 5; θ represents the diffraction angle of corresponding diffracted beams 7; m is the diffraction order of the corresponding diffracted beams 7; and λ is the operating wavelength of the incident optical signal 5 and diffracted beams 7.

The grating equation illustrates that optical radiation patterns that may be impractical to achieve with refractive or reflective structures may be readily achieved by diffracting the incident optical signal 5. Examples of optical radiation patterns formed by the diffracted beams 7 resulting from diffraction of optical signals 5 by apertures and gratings having various geometries are presented in Introduction to Fourier Optics, by J. W. Goodman, pages 62-74, published by McGraw-Hill, Inc., Library of Congress Catalog Number: 68-17184.

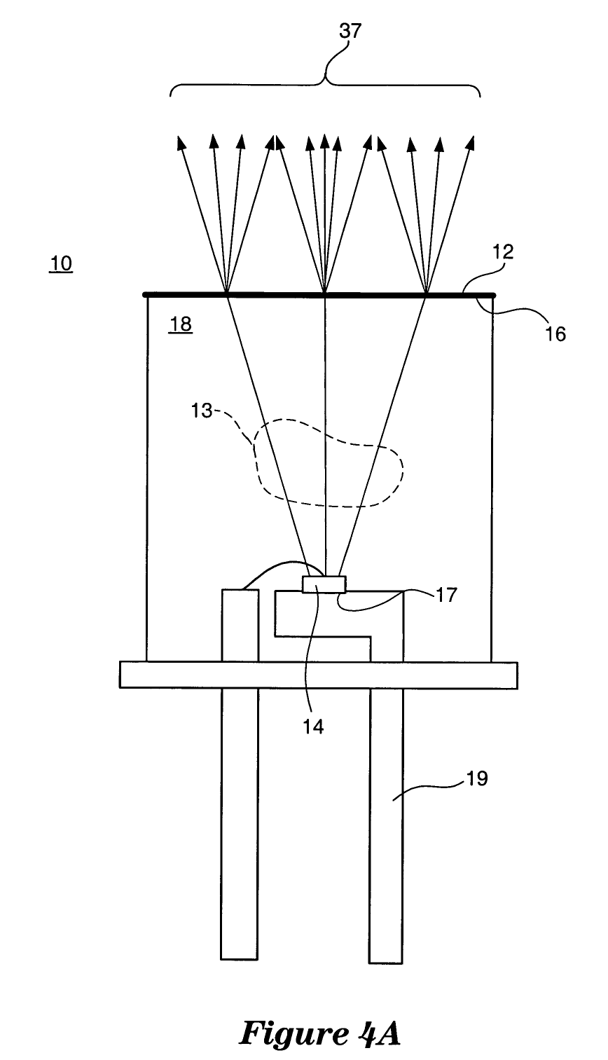

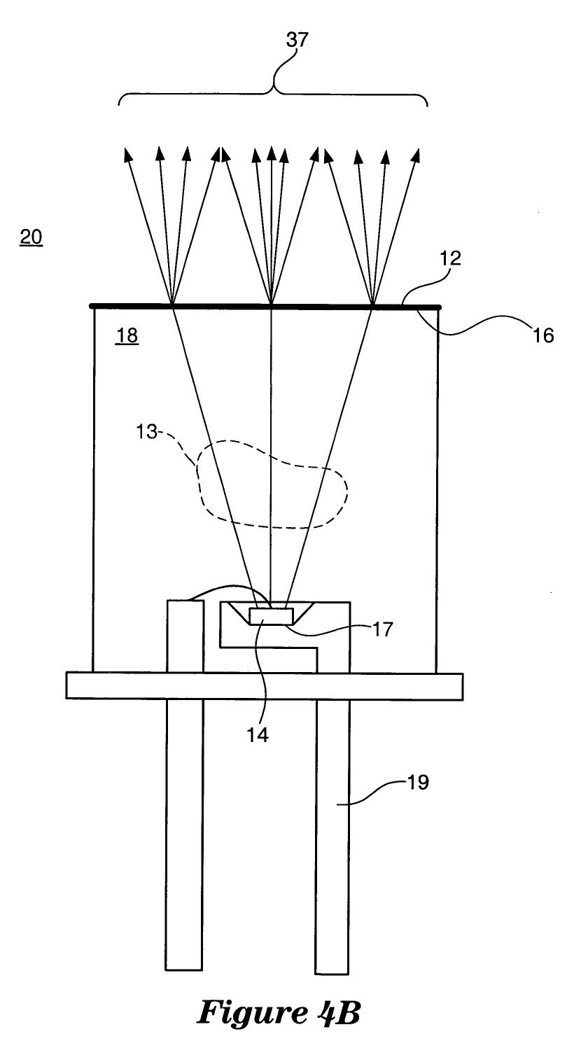

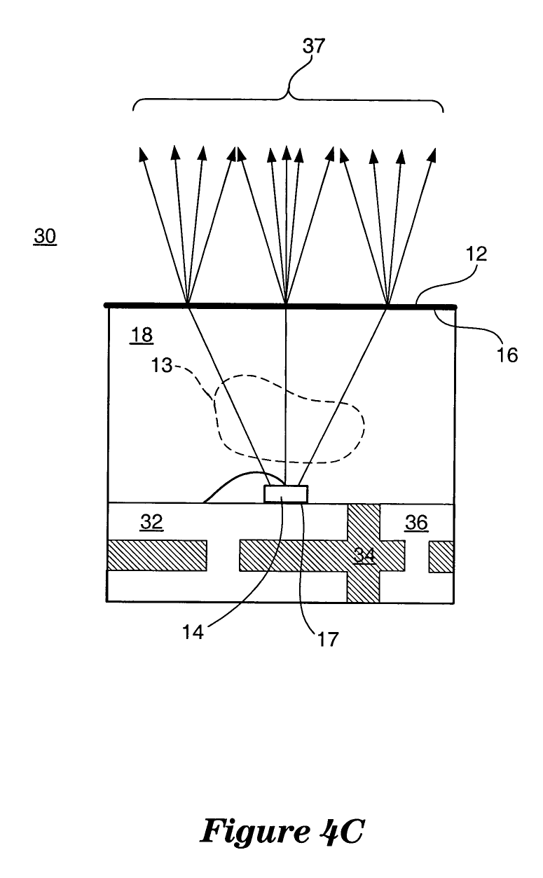

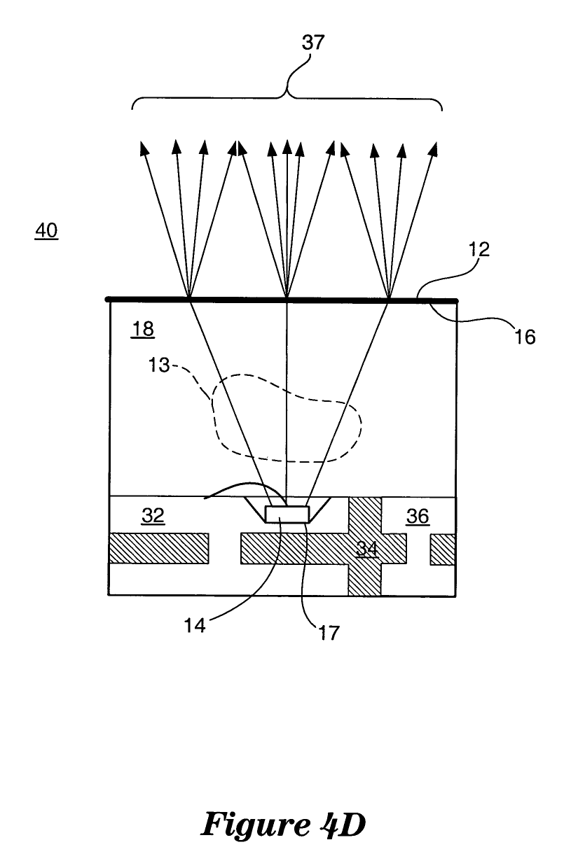

According to embodiments of the present invention shown in FIGS. 4A-4B, optical sources 10, 20, 30, 40 include diffractive elements 12 illuminated by optical signals 13 from optical emitters 14. The diffractive elements 12 diffract the optical signals 13 to form optical radiation patterns 37. The diffractive element 12 in each of the optical sources 10, 20, 30, 40 is integral with an encapsulant 18 that covers the optical emitter 14. Typically, the encapsulant 18 is epoxy or other transparent polymer cured via radiation, pressure or thermal treatment. However, the encapsulant 18 is alternatively any other optically suitable encapsulating material that encases the optical emitter 14.

The optical emitter 14 included in the optical sources 10, 20, 30, 40 is typically an LED, laser diode, or an array of LEDs and/or laser diodes. The optical signal 13 provided by the optical emitter 14 passes through the encapsulant 18 to the diffractive element 12. The diffractive element 12 is typically cast or transfer molded onto an outer surface 16 of the encapsulant 18, thereby integrating the diffractive element 12 into the encapsulant 18.

In the optical source 10 of FIG. 4A, the optical source 10 includes the optical emitter 14 positioned at a conductive mounting site 17 of a conductive lead 19. The optical source 20 of FIG. 4B differs from the optical source 10 of FIG. 4A in that the conductive mounting site 17 of the conductive lead 19 has a reflective cup or well, into which the optical emitter 14 is mounted.

In the optical source 30 of FIG. 4C, the optical emitter 14 has a mounting site 17 that is on a conductive heat sink 32, making the optical source 30 compatible with surface mount technologies and processes. The optical source 30 also includes an insulating substrate 34 that isolates the conductive heat sink 32 from a conductive contact 36. The optical source 40 of FIG. 4D differs from the optical source 30 of FIG. 4C in that the mounting site 17 of the conductive heat sink 32 includes a reflective cup or well, into which the optical emitter 14 is mounted.

The optical radiation patterns 37 produced by the optical sources 10, 20, 30, 40 are established by the characteristics of the optical signal 13 provided by the optical emitter 14 and the attributes of the diffractive element 12. The characteristics of the optical signal 13 provided by the optical emitter 14 can be tailored by the physical arrangement of one or more optical emitters 14 in an array, or by including one or more lenses, focusing elements, reflective elements or refractive elements in the path of the optical signal 13 between the optical emitter 14 and the diffractive element 12. The characteristics of the optical signal 13 can also be tailored by florescent dyes, phosphors or other secondary emitter in the path of the optical signal 13. When included in the optical sources 10, 20, 30, 40, the secondary emitter is deposited or integrated onto the optical emitter 14 or into the encapsulant 18.

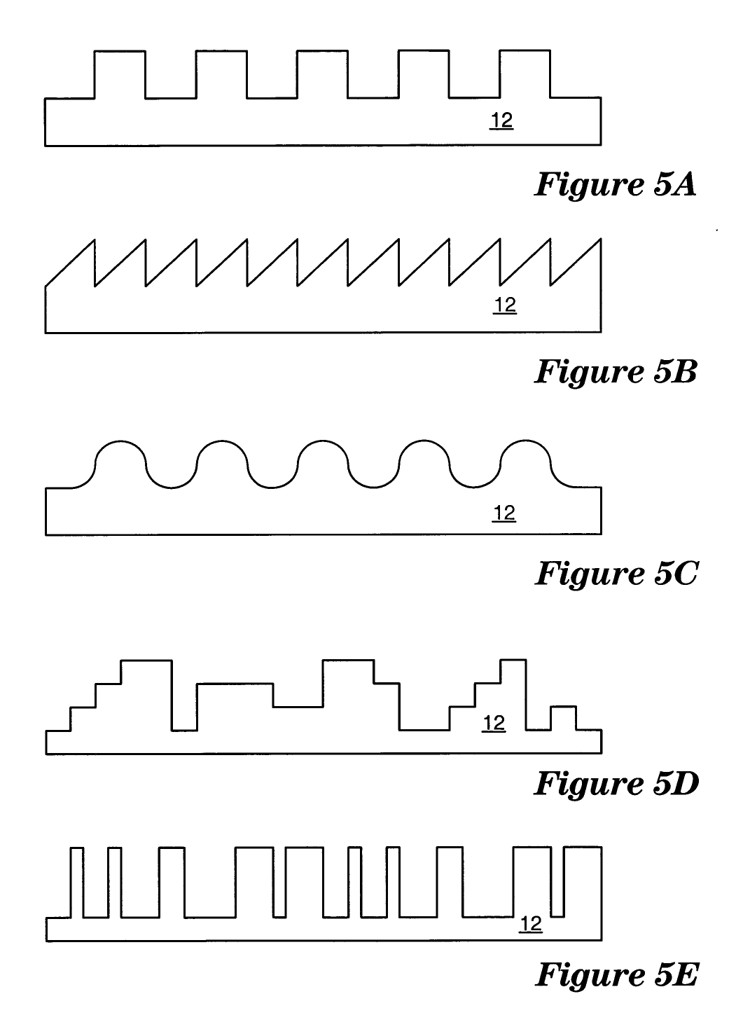

The attributes of the diffractive element 12 can be tailored based on the grating profile of the diffractive element 12. FIGS. 5A-5E show exemplary grating profiles for the diffractive element 12. FIG. 5A shows the diffractive element 12 having a binary grating profile, wherein the optical signal 13 provided by the optical emitter 14 is diffracted according to alternating steps in the grating profile. In FIG. 5B, the diffractive element 12 has a blazed, or sawtooth grating profile, wherein the optical signal 13 provided by the optical emitter 14 is diffracted according to a series of ramps in the grating profile. In FIG. 5C, the diffractive element 12 has a sinusoidal grating profile wherein the optical signal 13 provided by the optical emitter 14 is diffracted according to sinusoidal thickness variations in the grating profile. In FIG. 5D, the diffractive element 12 has a multiple phase-level grating profile wherein the optical signal 13 provided by the optical emitter 14 is diffracted according to stepped thickness variations in the grating profile. In FIG. 5E, the diffractive element 12 has a binary subwavelength grating profile wherein the optical signal 13 provided by the optical emitter 14 is diffracted as described in Vector-based Synthesis Of Finite Aperiodic Subwavelength Diffractive Optical Elements, by Prather et al., Journal of the Optical Society of America, Vol. 15, No. 6, June 1998, hereby incorporated by reference. While the grating profiles of FIGS. 5A-5E are exemplary, diffractive elements 12 having other grating profiles are alternatively included in the optical sources 10, 20, 30, 40.

The optical characteristics or attributes of the diffractive element 12 can also be varied based on the material used to form the diffractive element 12, or by embedding optically opaque material in the encapsulant 18 at physical separations on the order of the operating wavelength λ of the optical signal 13 incident on the embedded optically opaque material which can be used to customize or synthesize a desired optical radiation pattern 37.

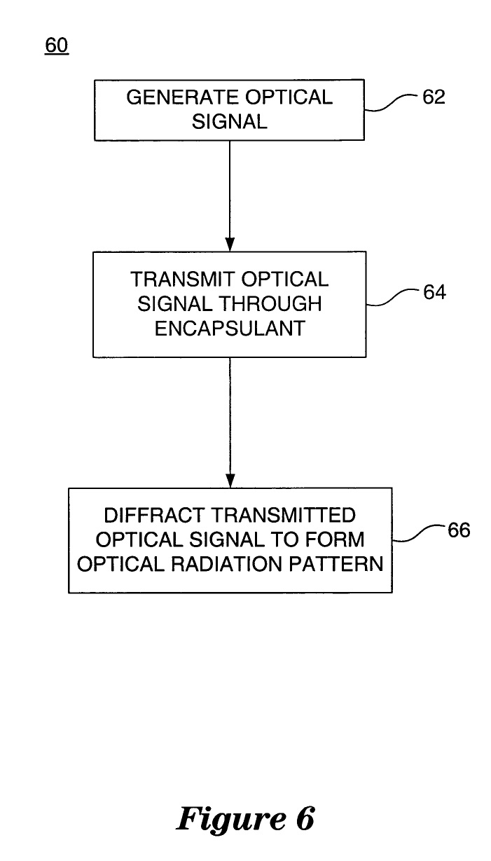

Alternative embodiments of the present invention are directed to a method for generating an optical radiation pattern 37, as shown in FIG. 6. Step 62 of the method 60 includes generating an optical signal 13, typically from an optical emitter 14. Step 64 includes transmitting the optical signal 13 through the encapsulant 18. In step 66, the optical signal 13 transmitted through the encapsulant 18 is diffracted to form a predesignated optical radiation pattern 37.

While the embodiments of the present invention have been illustrated in detail, it should be apparent that modifications and adaptations to these embodiments may occur to one skilled in the art without departing from the scope of the present invention as set forth in the following claims.

1. An optical source, comprising:
an optical emitter;
an encapsulant covering the optical emitter; and
a diffractive element integrated into the encapsulant, wherein the encapsulant passes light from the optical emitter to the diffractive element.

2. The optical source of claim 1 wherein the optical emitter includes at least one LED.

3. The optical source of claim 1 wherein the optical emitter is positioned at a conductive mounting site of a conductive lead.

4. The optical source of claim 1 wherein the optical emitter is positioned at a conductive mounting site of a conductive heat sink and the optical source is a surface mount device.

5. The optical source of claim 3 wherein the conductive mounting site includes a reflective cup.

6. The optical source of claim 4 wherein the conductive mounting site includes a reflective cup.

7. The optical source of claim 1 wherein at least one of the optical emitter and the encapsulant includes a secondary emitter.

8. An optical source, comprising:
an optical emitter providing an optical signal; and
a diffractive element integrated into an encapsulant covering the optical emitter, intercepting the provided optical signal and diffracting the optical signal to form a predesignated optical radiation pattern.

9. The optical source of claim 8 wherein the optical emitter is an LED.

10. The optical source of claim 8 wherein at least one of the optical emitter and the encapsulant includes a secondary emitter.

11. The optical source of claim 8 wherein the diffractive element has one of a binary grating profile, a sawtooth grating profile, a sinusoidal grating profile, a multiple phase-level grating profile, and a binary subwavelength grating profile.

12. The optical source of claim 8 wherein the encapsulant covering the optical emitter encases the optical emitter.

13. The optical source of claim 9 wherein the optical emitter is positioned at a conductive mounting site of a conductive lead.

14. The optical source of claim 11 wherein the optical emitter is positioned at a conductive mounting site of a conductive lead.

15. The optical source of claim 9 wherein the optical emitter is positioned at a conductive mounting site of a conductive heat sink and the optical source is a surface mount device.

16. The optical source of claim 11 wherein the optical emitter is positioned at a conductive mounting site of a conductive heat sink and the optical source is a surface mount device.

17. A method, comprising:
generating an optical signal;
transmitting the optical signal through an encapsulant; and
diffracting the optical signal transmitted through the encapsulant to form a predesignated optical radiation pattern.

18. The method of claim 17 wherein generating the optical signal is provided by an optical emitter.

19. The method of claim 18 wherein diffracting the optical signal transmitted through the encapsulant is provided by a diffractive element integral to the encapsulant.

20. The method of claim 19 wherein the diffractive element has one of a binary grating profile, a sawtooth grating profile, a sinusoidal grating profile, a multiple phase-level grating profile, and a binary subwavelength grating profile.
